(19) United States
(12) Patent Application Publication
(10) Pub. No.: US 2026/0047128 A1
(43) Pub. Date: Feb. 12, 2026

(54) SEMICONDUCTOR DEVICES AND METHODS FOR FABRICATION THEREOF

(71) Applicant: TAIWAN SEMICONDUCTOR MANUFACTURING COMPANY, LTD., Hsinchu (TW)

(72) Inventors: Wei Shun HUANG, Tainan (TW); Tsung-Yin HSU, Tainan (TW); Ying Ming WANG, Tainan (TW); I-I CHENG, Tainan (TW); Li-Yi CHEN, Tainan (TW)

(21) Appl. No.: 18/978,147

(22) Filed: Dec. 12, 2024

Related U.S. Application Data
(60) Provisional application No. 63/679,644, filed on Aug. 6, 2024.

(51) Int. Cl. H10D 30/62; H01L 21/311; H01L 21/762; H10D 30/01; H10D 62/13; H10D 84/83

(52) U.S. Cl. CPC H10D 30/62; H01L 21/31144; H01L 21/76224; H10D 30/024; H10D 62/151; H10D 84/834

(57) ABSTRACT

Embodiments of the present disclosure provide an integrated circuit including multiple source/drain physical dimensions for the same type devices co-exist in the same chip. Some embodiments provide methods for modulating source/drain physical dimension to fine-tune parasite capacitance, such as parasite capacitance between gate and drain Cgd, and resistance, such as resistance for source/drain contact Rc in analog or RF (radio frequency) devices.

### CROSS-REFERENCE TO RELATED APPLICATIONS

This application claims priority to the U.S. Provisional Patent Application Ser. No. 63/679,644, filed Aug. 6, 2024, which is incorporated by reference in its entirety.

### BACKGROUND

The semiconductor industry has experienced continuous rapid growth due to constant improvements in the integration density of various electronic components. For the most part, this improvement in integration density has come from repeated reductions in minimum feature size, allowing more components to be integrated into a given chip area. As minimum feature size reduces, advanced technologies may be applied to achieve an aggressive pitch shrink on the contact to gate pitch. However, this results in a remarkably increased parasitic capacitance from the gate to drain site (Cgd) and Rc (contact resistance), which is not good for analog and RF device applications due to serious RC delay and signal loss.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, and 1D schematically illustrate a semiconductor device according to embodiments of the present disclosure.

FIG. 2 is a flow chart of a method for manufacturing of a semiconductor device according to embodiments of the present disclosure.

FIGS. 3A, 3B, 3C, 4A, 4B, 4C, 5, 6A, 6B, 7, 8, 9, 10A, 10B, 11, 12, 13, and 14A-14B schematically illustrate various stages of manufacturing a semiconductor device according to embodiments of the present disclosure.

FIGS. 15A, 15B, 15C, and 15D schematically illustrate modulation of source/drain to according to circuit design.

FIGS. 16A-16B schematically illustrate a semiconductor device according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 64 degrees or at other orientations) and the spatially relative descriptors used herein may likewise be interpreted accordingly.

The foregoing broadly outlines some aspects of embodiments described in this disclosure. While some embodiments described herein are described in the context of FinFETs, implementations of some aspects of the present disclosure may be used in other processes and/or in other devices, such as planar FETs, nanosheet FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of the present disclosure provide an integrated circuit including multiple source/drain physical dimensions for the same type devices co-exist in the same chip. Some embodiments provide methods for modulating source/drain physical dimension to fine-tune parasite capacitance, such as parasite capacitance between gate and drain Cgd, and resistance, such as resistance for source/drain contact Rc in analog or RF (radio frequency) devices. Embodiments of the present disclosure provides easy implementation of source/drain dimension tuning on different device regions by mask shadowing, thereby, achieving customized Cgd and Rc based on device requirement in different regions.

Embodiments of the present disclosure provide methods of source/drain formation to customize dimensions, such as critical dimension, height, area, for different regions to reduce RC delay and parasite capacitance. In some embodiments, dimensions of source/drain regions may be controlled by patterning and fine-tuning fin recess etch process to obtain desirable position and/or shape of fin sidewall spacer, and location of shallow trench isolation. With combination of the fin sidewall spacer and/or STI location, a variety of source/drain dimensions may be created in different device regions. For example, to obtain low Cgd or low Rc especially for RF devices require higher f_{T} (current gain) and fmax (maximal frequency).

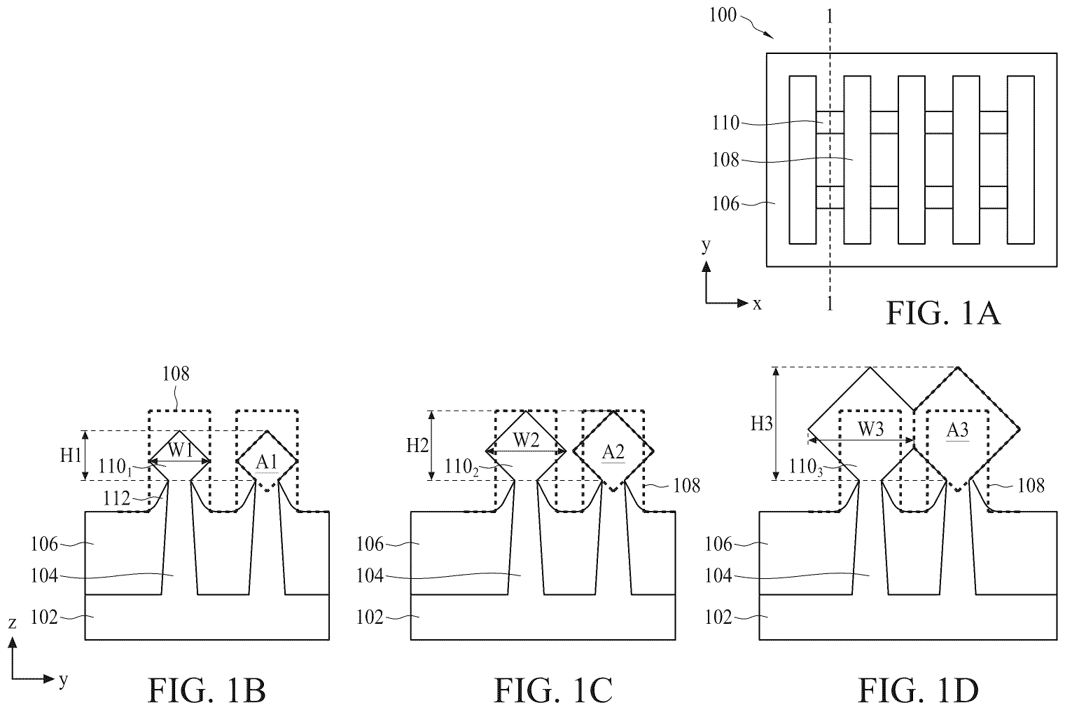

FIGS. 1A-1D schematically illustrate a semiconductor device 100 according to embodiments of the present disclosure. FIG. 1A is a schematic plan view of the semiconductor device 100. FIGS. 1B-1D are schematic cross sectional views of the semiconductor device 100 along the 1-1 line in FIG. 1A resulting in different processing conditions. The semiconductor device 100 may include FinFET devices. The semiconductor device 100 may include fin structures 104 formed on a semiconductor substrate 102. Lower portions of the fin structures 104 are surrounded by an isolation region 106. The fin structures 104 extend above the isolation region 106. Gate structures 108 are formed over and across the fin structures 104. The gate structures 108 cover a portion of the fin structures 104. The fin structures 104 not covered by the gate structure 108 are recess etched below the isolation region 106 and source/drain regions 110 are epitaxially grown from the exposed surfaces of the fin structures 104. The source/drain regions 110, the fin structures 104 under the gate structure 108, and the gate structure 108 form a FinFET structure. Conductive features (not shown) may be formed over the source/drain regions 110 to provide electrical connection.

In some embodiments, physical dimensions, such as critical dimension, height, and cross-sectional area, of the source/drain regions 110 are tuned according to device requirement. The physical dimensions of the source/drain regions 110 may be adjusted by tuning recess etching process and/or epitaxial growth process. In some embodiments, height of fin sidewalls 112 may be tuned to obtain different physical dimension of the source/drain region 110.

FIGS. 1B, 1C, and 1D are examples of the source/drain regions 110 with different dimensions to achieve different performance. In FIG. 1B, source/drain regions 1101 has a heigh H1, a width W1, and an area A1. In FIG. 1C, source/drain regions 1102 has a heigh H2, a width W2, and an area A2. In FIG. 1D, source/drain regions 1103 has a heigh H3, a width W3, and an area A3. The height H1 is shorter than the height H2 while the height H3 is taller than the height H2. The width W1 is narrower than the width W2 while the width W3 is wider than the width W2. The area of the source/drain region 110 is approximately related to product of the height and the width of the source/drain region 110. The area A1 is smaller than the area A2 while the area A3 is larger than the area A2.

The width of the source/drain region 110 may be proportional to the size of the contact area between the source/drain region 110 and the contact feature formed therein. A wider source/drain region 110 has a lower resistance Rc. Thus, to reduce resistance Rc, the source/drain region 110 may be tuned to have a larger width. In this case, the source/drain 110₃ has a lower resistance Rc than the source/drain region 110₂, which has a lower resistance than the source/drain region 110₁.

When the source/drain region 110 overlaps with the gate structure 108, a parasitic capacitance Cgd may occur. A larger cross sectional area of the source/drain region 110 may result in a larger parasitic capacitance Cgd. Thus, to parasitic capacitance Cgd, the source/drain region 110 may be tuned to have a smaller cross sectional area. In the examples in FIGS. 1B-1D, the source/drain 1103 has a higher parasitic capacitance Cgd than the source/drain region 110₂, which has a higher parasitic capacitance Cgd than the source/drain region 110₁. With a lower parasitic capacitance Cgd and a higher resistance, the source/drain region 110₁ may be desirable for RF devices. With a lower resistance Rc and a higher parasitic capacitance Cgd, the source/drain region 110₃ may be desirable for analog devices. With a medium resistance Rc and a medium parasitic capacitance Cgd, the source/drain region 110₂ may be suitable for digital devices.

According to embodiments of the present disclosure, physical dimensions of the source/drain regions 110 may be tuned according to the function of the semiconductor devices.

In some embodiments, when a chip includes multiple circuit regions, such as digital circuit regions, analog circuit regions, RF circuit region, physical dimensions of source/drain regions in different circuit regions may be customized according to the circuit function. Different physical dimensions in source/drain regions may be achieve using mask shadowing.

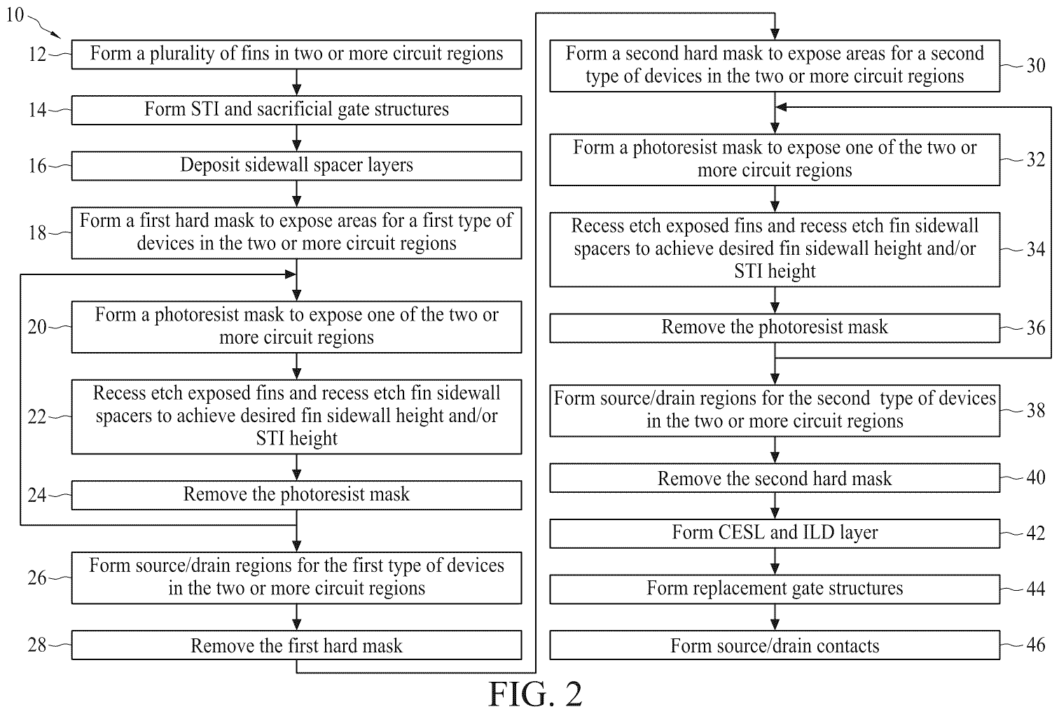

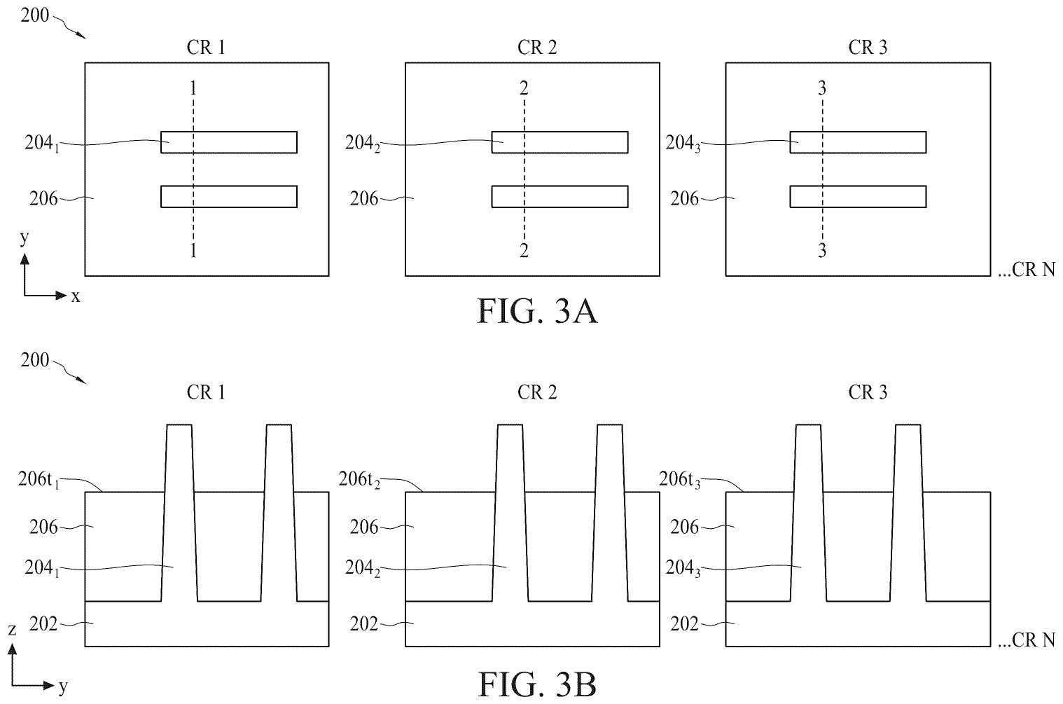

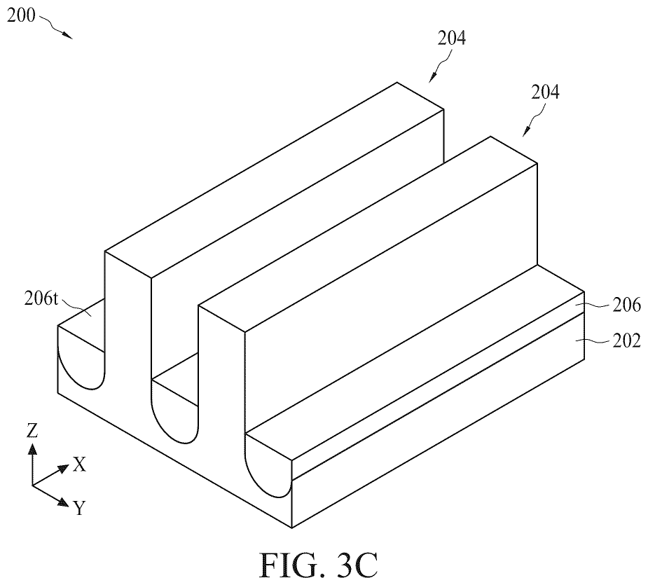

FIG. 2 is a flow chart of a method 10 for manufacturing of a semiconductor device having source/drain regions with different dimensions in different circuit areas according to embodiments of the present disclosure. FIGS. 3A, 3B, 3C, 4A, 4B, 4C, 5, 6A, 6B, 7, 8, 9, 10A, 10B, 11, 12, 13, and 14A-14B schematically illustrate various stages of manufacturing a semiconductor device 200 according to embodiments of the present disclosure. In some embodiments, the semiconductor device 200 may be fabricated using the method 10.

At operation 12 of the method 10, fin structures 204 are formed on a substrate 202, and an isolation region 206 is formed in trenches between the fin structures 204, as shown in FIGS. 3A-3C. FIG. 3A is a schematic top view of the semiconductor device 200 according to the present disclosure. The semiconductor device 200 includes two or more circuit regions. In FIG. 3A, portions of three circuit regions CR 1, CR 2, and CR 3 are shown. Less or more circuit regions may be included in the semiconductor device 200. In some embodiments, N circuit regions may be included in the semiconductor device 200. In some embodiments, the circuit region CR 1 include analogy circuits, the circuit region CR 2 includes digital circuits, and the circuit region CR 3 includes RF circuits. The circuit regions CR 1, CR 2, and CR 3 are formed on the same substrate and may be within the same chip. FIG. 3B includes schematic cross sectional views of the circuit regions CR 1, CR 2, CR 3 along the lines 1-1, 2-2, 3-3 respectively. FIG. 3C is a schematic perspective view of one of the circuit regions CR 1, CR 2, CR 3.

The substrate 202 may include a single crystalline semiconductor material such as, but not limited to Si, Ge, SiGe, GaAs, InSb, GaP, GaSb, InAlAs, InGaAs, GaSbP, GaAsSb, and InP. In some embodiments, the substrate 202 is a silicon substrate. The substrate 202 may include various doping configurations depending on circuit design. For example, the substrate 202 may include one or more p-doped regions and one or more n-doped regions. A p-type substrate or n-type substrate may be used and the substrate 202 may include various doped regions, depending on design requirements. In some embodiments, the doped regions may be doped with p-type or n-type dopants. For example, the doped regions may be doped with p-type dopants, such as boron or BF₂; n-type dopants, such as phosphorus or arsenic; and/or combinations thereof. The doped regions may be configured for forming n-type % FinFET and p-type FinFET. In some embodiments, each of the circuit regions CR 1, CR 2, and CR 3 include both n-type devices and p-type devices.

The fin structures 204 are then formed using one or more patterning and etching processes. The isolation region 206 is formed in the trenches between the fin structures 204 by a suitable deposition followed by an etch back process. The bottom profile of the isolation region 206 is shown to be curved as an example. Depending on pitch and/or height of the fin structures 204, a bottom profile of the isolation region 206 may vary, for example curved, substantially flat, or other shapes. The isolation region 206 may be formed by a high-density plasma chemical vapor deposition (HDP-CVD), a flowable CVD (FCVD), or other suitable deposition process. In some embodiments, the isolation region 206 may include silicon oxide, silicon nitride, silicon oxynitride, fluorine-doped silicate glass (FSG), a low-k dielectric, combinations thereof. In some embodiments, the isolation region 206 is formed to cover the fin structures 204 by a suitable deposition process to fill the trenches between the fin structures 204, a planarization process may be performed to expose the fin structures 204, and then recess etched using a suitable anisotropic etching process to expose a portion of the fin structures 204, as shown in FIGS. 3B and 3C. In some embodiments, the fin structures 204 protrude over a top surface 206t.

The fin structures 204 in the circuit regions CR 1, CR 2, CR 3 are denoted as fin structures 204₁, 204₂, 204₃ respectively. The fin structures 204₁, 204₂, 204₃ in the circuit regions CR 1, CR 2, CR 3 extend over top surfaces 206t₁, 206t₂, 206t₃ of the isolation region 206. In some embodiments, the top surfaces 206t₁, 206t₂, 206t₃ may be substantially at the same level in the z-direction after operation 12.

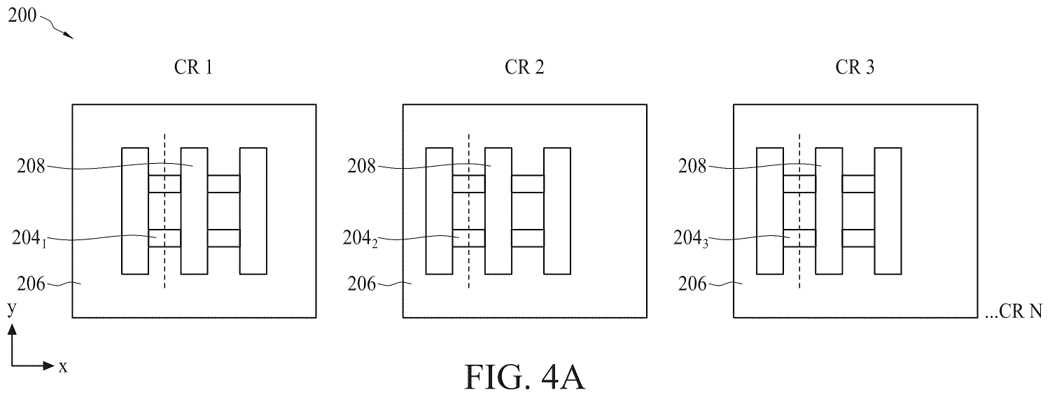

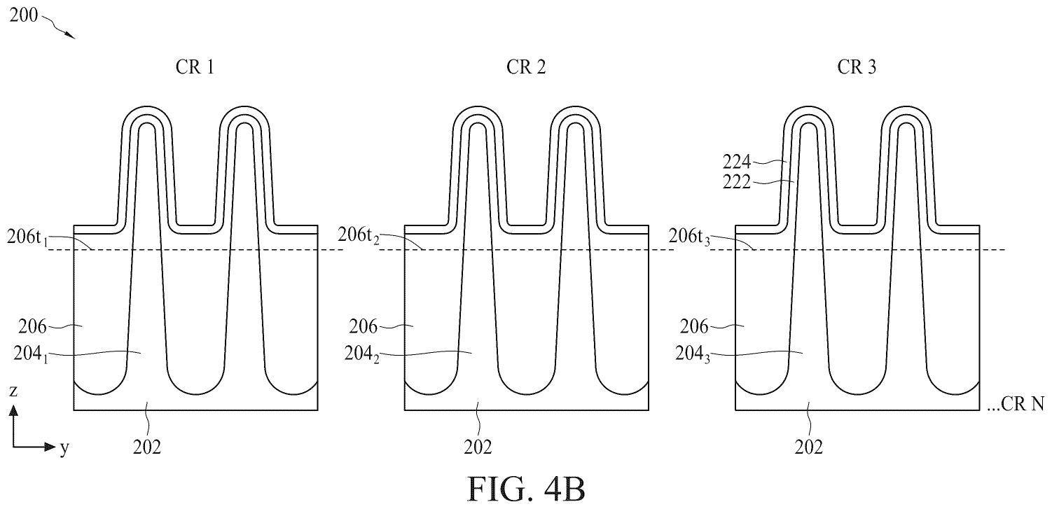

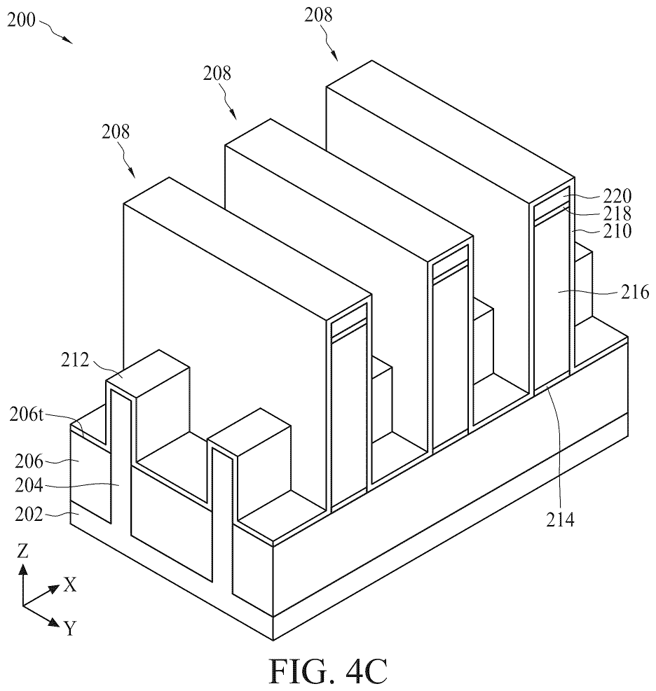

At operation 14, sacrificial gate structures 208 are formed over the fin structures 204, as shown in FIGS. 4A-4C. FIG. 4A is a schematic top view of the semiconductor device 200 according to the present disclosure. FIG. 4B includes schematic cross sectional views of the circuit regions CR 1, CR 2, CR 3 along the lines 1-1, 2-2, 3-3 respectively. FIG. 4C is a schematic perspective view of one of the circuit regions CR 1, CR 2, CR 3.

The sacrificial gate structures 208 includes a sacrificial gate dielectric layer 214 is conformally formed over the fin structures 204 and the isolation region 206 in all circuit regions CR 1, CR 2, CR 3 simultaneously. The sacrificial gate dielectric layer 214 is formed over the fin structures 204 and the isolation region 206. The sacrificial gate dielectric layer 214 may include silicon oxide, silicon nitride, a combination thereof, or the like. The sacrificial gate dielectric layer 214 may be deposited or thermally grown according to acceptable techniques, such as thermal CVD, CVD, ALD, and other suitable methods.

A sacrificial gate electrode layer 216 is deposited on the sacrificial gate dielectric layer 214 and then planarized, such as by a CMP process. The sacrificial gate electrode layer 216 includes silicon such as polycrystalline silicon, amorphous silicon, poly-crystalline silicon-germanium (poly-SiGe), or the like. In some embodiments, the sacrificial gate electrode layer 216 is subjected to a planarization operation. The sacrificial gate electrode layer 216 may be deposited using CVD, including LPCVD and PECVD, PVD, ALD, or other suitable process. In some embodiments, a pad layer 218, and a mask layer 220 are sequentially deposited over the sacrificial gate electrode layer 216. The pad layer 218 may include silicon nitride. The mask layer 220 may include silicon oxide. A patterning operation is performed on the mask layer 220, the pad layer 218, the sacrificial gate electrode layer 216, and the sacrificial gate dielectric layer 214 to form the sacrificial gate structures 208 using one or more etching processes, such as one or more plasma etching processes or one or more wet etching processes. In some embodiments, the mask layer 220 and pad layer 218 are first patterned using a patterning process. The sacrificial gate electrode layer 216 is then patterned using the patterned mask layer 220 and pad layer 218 as an etching mask. In some embodiments, the sacrificial gate electrode layer 216 may be etched by an anisotropic etching, such as a reactive ion etching (RIE) process. The anisotropic etching has a greater etching rate along the Z direction than etching rates along the X and Y directions. During the etching of the sacrificial gate electrode layer 216, the sacrificial gate dielectric layer 214 on the fin structures 204 may act as an etch stop to prevent the etchant from removing the fin structures 204.

In some embodiments, after patterning the sacrificial gate electrode layer 216, any exposed residual sacrificial gate dielectric layer 214 is removed by a suitable etch process. In some embodiments, the residual sacrificial gate dielectric layer 214 can be etched by tuning one or more parameters, such as etchant, etching temperature, etching solution concentration, etching pressure, source power, radio frequency (RF) bias voltage, etchant flow rate, of the etch process for etching the sacrificial gate electrode layer 216.

The sacrificial gate structure 208 covers a portion of the fin structures 204. The portion of the fin structures 204 covered by the sacrificial gate structures 208 eventually form a channel region.

In operation 16, one or more dielectric layers are deposited over the fin structures 204 and the sacrificial gate structures 208, as shown in FIGS. 4A-4C. The one or more dielectric layers may be uniformly deposited. The one or more dielectric layers on sidewalls of the sacrificial gate structures 208 are referred to as gate sidewall spacers 210. The one or more dielectric layers on sidewalls of the fin structures 204 are referred to as fin sidewall spacers 212. In some embodiments, the gate sidewall spacers 210 and the fin sidewall spacers 212 include the same composition of dielectric layers. In some embodiments, in the subsequent the fin etch back process, sidewalls of the sacrificial gate structures 208 remain covered by the gate sidewall spacers 210 while a desirable portion of the fin sidewall spacer 212 remain protruding over the isolation region 206.

The one or more dielectric layers may be formed by ALD or CVD, or any other suitable method. The one or more dielectric layers may be composed by various material, such as SiON, SiONC, SIN, SiO, etc, that provide different etching selectivity to customize sidewall spacer remainders during subsequent fin etch back process. The one or more dielectric layers are formed by a suitable process. In the example of FIG. 4B, two spacer layers 222 and 224 are shown. It should be noted, the gate sidewall spacer 210 and the fin side wall spacer 212 may include a single dielectric layer or three or more dielectric layers. The spacer layer 222 and spacer layer 224 are formed by blanket deposition sequentially. In some embodiments, an anisotropic etching may be performed to remove the spacer layer 222 and spacer layer 224 from horizontal surfaces, such that the spacer layer 222 and spacer layer 224 are positioned on sidewalls of the sacrificial gate structures 208.

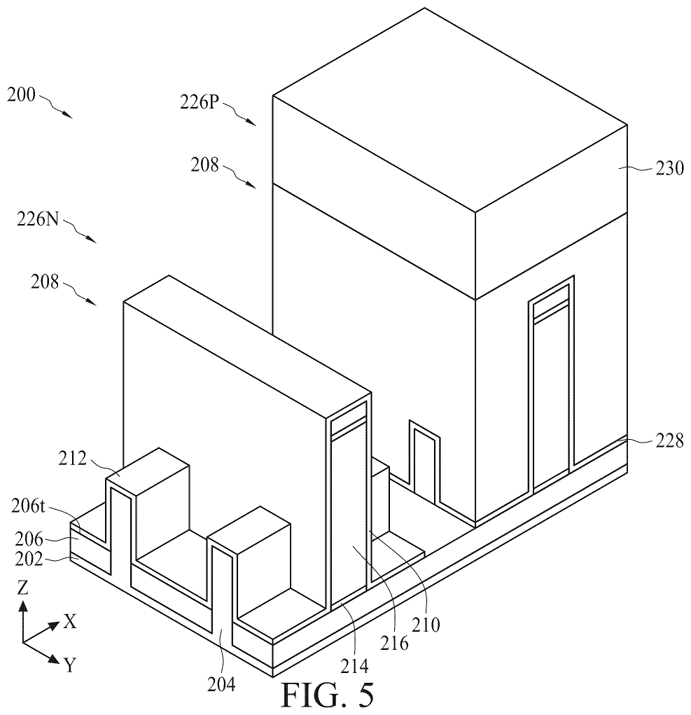

In operation 18, a mask layer 228 is disposed over the semiconductor device 100 and patterned to cover areas of one type of devices, as shown in FIG. 5. FIG. 5 is a schematic perspective view of a portion of any circuit areas CR 1, CR 2, CR 3. In FIG. 5, a p-type device area 226P and a n-type device area 226N are shown. In some embodiments, the mask layer 228 may be deposited by ALD or other suitable process. The mask layer 228 may be patterned to protect areas of a first type devices, such as P-type device areas, and expose areas of a second type devices, such as n-type device areas, during subsequent etch back and epitaxial processes. The mask layer 228 may include a dielectric material. In some embodiments, the mask layer 228 incudes materials with etch selectivity with the spacer layers 224.

A photoresist layer 230 is deposited and patterned to expose areas for subsequent source/drain formation. In the example of FIG. 5, n-type device areas 226N are exposed. Other areas, including the p-type device areas 226P, are covered by the photoresist layer 230. After patterning the photoresist layer 230, the mask layer 228 exposed by the photoresist layer 230 is removed, the n-type device areas 226N may be exposed to an etch back process and epitaxial deposition.

According to embodiments of the present disclosure, the fin structures 204 in the n-type device areas 226N in different circuit regions CR 1, CR 2, CR 3 may be recessed in separate etch processes. In one embodiment, operations 20, 22, and 24 may be repeated for each circuit region CR 1, CR 2, CR 3.

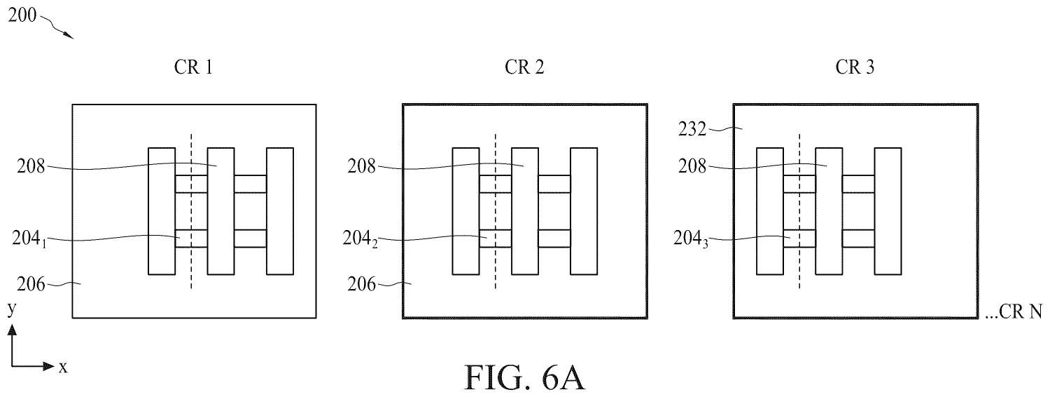

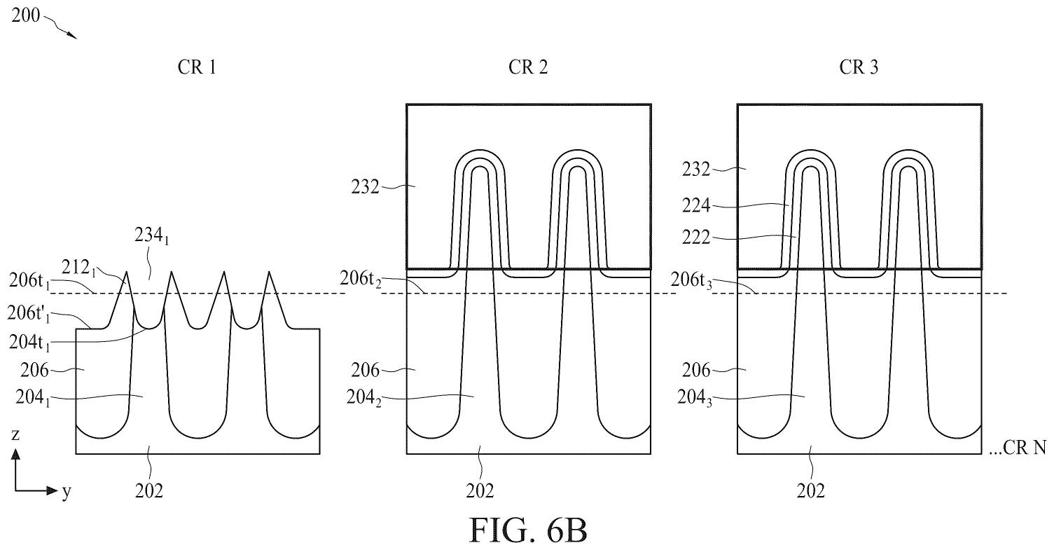

In operation 20, a photoresist mask is formed over the semiconductor devices to expose the n-type device areas 226N in a first one of the circuit regions CR 1, CR 2, CR 3, as shown in FIGS. 6A-6B. A photoresist layer 232 is deposited over the semiconductor device 200 and then patterned to expose the n-type device areas in the circuit region CR 1. The patterned photoresist layer 232 covers the p-type device areas, and the other circuit regions, such as circuit regions CR 2, CR 3.

In operation 22, the fin structures 204 not covered by the photoresist layer 232 or the sacrificial gate structures 208, are recess etched forming source/drain recesses 234₁ above the fin structures 204₁, as shown in FIG. 6B. In some embodiments, the fin structures 204 are recessed to a level below the top surface 206t of the isolation region 206. After operation 22, a top surface 204t₁ of the fin structures 204₁ are recessed to a level below the top surface 206t of the isolation region 206. The fin sidewall spacers 212 are also at least partially removed. In operation 22, fin sidewall spacer portions 212₁ remain on sides of the source/drain recesses 234₁. In some embodiments, the exposed isolation region 206 is also recessed to a lower level. In FIG. 6B, after fin recess etch process in operation 22, portions of the isolation region 206 not immediately contact the fin structures 204 are recessed to a level 206t′₁.

In some embodiments, the fin sidewall spacers 212 may be recessed during recess etch of the fin structures 204. In other embodiments, the fin sidewall spacers 212 may be removed using a separate process. In some embodiments, heights and angles of the fin sidewall spacer portions 212₁ may be controlled to achieve desired shape of the source/drain regions to be formed from the fin structures 204. For example, the heights of the fin sidewall spacer portions 212₁, along the z-direction, from a top surface 206t of the isolation region 206 may be controlled to define critical dimension and/or shape of the source/drain regions to be formed. Various factors may be considered when selecting heights and angles of the fin sidewall spacer portions 212₁ to achieve desired shape of the source/drain features to be formed, for example, the pitch of the fin structures 204, the width of the fin structures 204 along the Y-axis, the height of the fin structures 204 over the top surface 206t of the isolation region 206, and other relevant geometry and/or material properties of the fin structures 204 and source/drain regions to be formed. When the fin sidewall spacers 212 includes two or more dielectric layers, the etch selectivity between the two or more dielectric layers may be used to control the shape and dimension of the fin sidewall spacer portions 212₁. Depending on the dimension of the fin sidewall spacer portions 212₁, the fin sidewall spacer portions 212₁ may include all of the two or more dielectric layers in the fin sidewall spacers 212 or include fewer dielectric layers than the fin sidewall spacers 212.

In some embodiments, suitable dry etching and/or wet etching may be used to remove the semiconductor material in the fin structures 204 and a desirable amount of fin sidewall spacers 212 and isolation region 206. The recess etch process in operation 22 is designed or customized according to the circuit function of the circuit region being processed. In FIG. 6A-6B, the fin structures 204₁ in the circuit region CR 1 are being recessed.

The circuit region CR 1 includes analog circuits. The analog circuits performance better with lower source/drain contact resistances and may not be sensitive to parasitic capacitance between source/drain regions and the gates. Therefore, it is desirable to have source/drain regions with large volumes, i.e. greater width W1 and/or greater height H1. It has been observed that when the fin sidewall spacer portions 212₁ are smaller, greater source/drain height and source/drain width may be achieved. In some embodiments, the fin sidewall spacer portions 212₁ may include the inner most dielectric layer 222 of the two or more layers in the fin sidewall spacers 212. The lower level of the isolation region 206 may also facilitate greater volume of the source/drain regions to be formed.

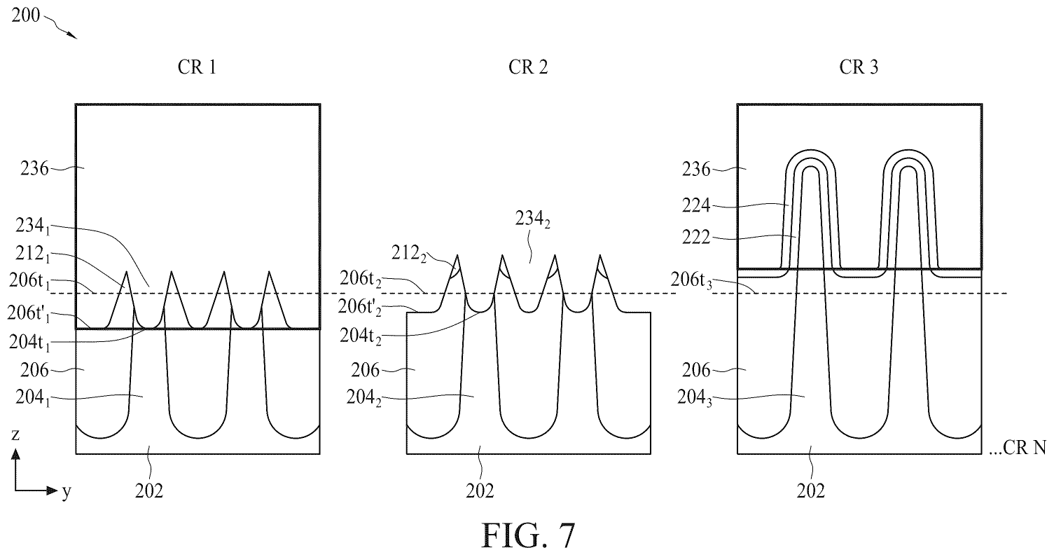

In operation 24, the photoresist layer 230 is removed for subsequent processing. When the semiconductor device 200 includes two or more circuit regions, the operations 20, 22, 24 may be repeated for other circuit regions to achieve different recess etch result. As shown in FIG. 7, the operation 20 is performed to deposit and pattern a second photoresist layer 236 on the semiconductor device 200 to expose the second circuit region CR 2 in the n-type device areas.

The operation 22 is then performed to customarily etch back the fin structures 204₂ according to circuit function of the second circuit region CR 2. The fin structures 204₂ not covered by the photoresist layer 236 or the sacrificial gate structures 208, are recess etched forming source/drain recesses 234₂ above the fin structures 204₂. A top surface 204t₂ of the fin structures 204₂ are recessed to a level below the top surface 206t of the isolation region 206. Fin sidewall spacer portions 212₂ remain on sides of the source/drain recesses 234₂. Portions of the isolation region 206 not immediately contact the fin structures 204 are recessed to a level 206t′₂.

In some embodiments, the circuit region CR 2 includes digital circuits. The digital circuits are not as sensitive to source/drain contact resistances as the analog circuits and are not as sensitive to parasitic capacitance between source/drain regions and the gates as the RF circuits. Therefore, it is desirable to have a balanced approach to lower contact resistance and parasitic capacitance. In some embodiments, the recess etch the circuit region CR 2 may be performed to obtain source/drain regions with medium volumes. It has been observed that when the fin sidewall spacer portions 212₂ are at a medium height, medium source/drain height and source/drain width may be achieved. In some embodiments, the fin sidewall spacer portions 212₂ may include a larger portion of the inner most spacer layer 222 and a smaller portion of the outer spacer layer 224.

As shown in FIG. 7, the fin sidewall spacer portions 212₂ in the circuit region CR 2 are bigger and at a higher level than the fin sidewall spacer portions 212₁ in the circuit region CR 1. The source/drain recesses 234₂ in the circuit region CR 2 are located at a higher level than the source/drain recesses 234₁ in the circuit region CR 1. The isolation region 206 is recessed for a less amount in the circuit region CR 2 than in the circuit region CR 1. The level 206t′₂ in the circuit region CR 2 is located at a higher level than the level 206t′₁ in the circuit region CR 1.

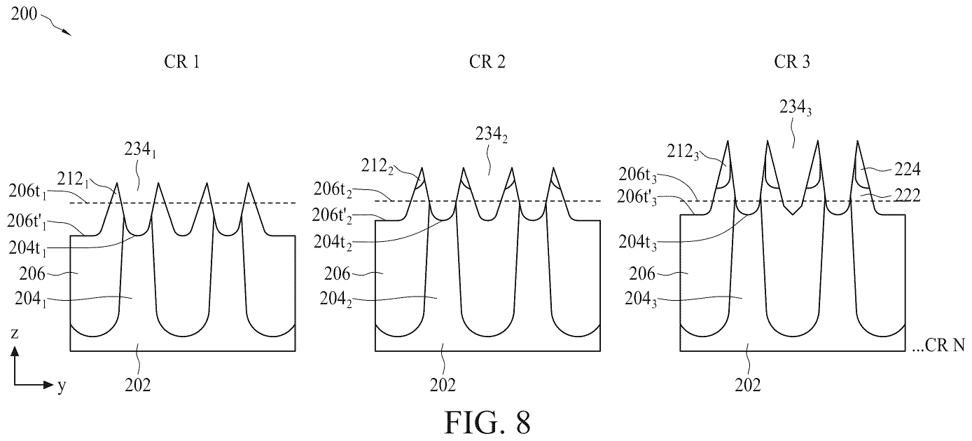

The photoresist layer 236 is then removed for subsequent processes. The operations 20, 22, 24 may be repeated for other circuit regions to achieve different recess etch result until all the circuit regions are processed. As shown in FIG. 8, the operations 20, 22, 24 are performed to etch back the fin structures 204₃ according to circuit function of the third circuit region CR 3. The fin structures 204₃ are recess etched forming source/drain recesses 234₃ above the fin structures 204₃. A top surface 204t₃ of the fin structures 204₃ are recessed to a level below the top surface 206t of the isolation region 206. Fin sidewall spacer portions 212₃ remain on sides of the source/drain recesses 234₃. Portions of the isolation region 206 not immediately contact the fin structures 204 are recessed to a level 206t₃′.

In some embodiments, the circuit region CR 3 includes RF circuits. The RF circuits are more sensitive to parasitic capacitance between source/drain regions and the gates than to source/drain contact resistances. Therefore, it is desirable to source/drain regions with low parasitic capacitances, thus, smaller volume. In some embodiments, the recess etch the circuit region CR 3 may be performed to obtain source/drain regions with smaller volumes. It has been observed that when the fin sidewall spacer portions 212₃ are at a higher height, smaller source/drain regions may be achieved.

As shown in FIG. 8, the fin sidewall spacer portions 212₃ in the circuit region CR 3 are bigger and at a higher level than the fin sidewall spacer portions 212₂ in the circuit region CR 2. The source/drain recesses 234₃ in the circuit region CR 3 are located at a higher level than the source/drain recesses 234₂ in the circuit region CR 2 and the source/drain recesses 234₁ in the circuit region CR 1. The isolation region 206 is recessed for a less amount in the circuit region CR 3 than in the circuit region CR 2 and in the circuit region CR 1. The level 206t′₃ in the circuit region CR 3 is located at a higher level than the level 206t′₂ in the circuit region CR 2 and the level 206t′₁ in the circuit region CR 1.

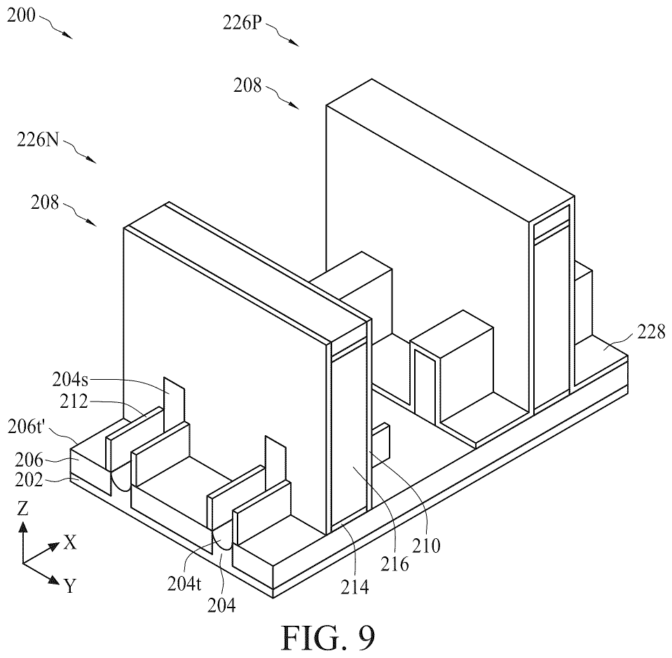

FIG. 9 is a schematic perspective view of a portion of any circuit areas CR 1, CR 2, CR 3. In FIG. 9, a p-type device area 226P and a n-type device area 226N are shown. The fin structures 204 in the n-type device area 226N are recess etched with the top surface 204t exposed between the fin sidewall spacer portions 212 and a side surface 204s exposed from the gate sidewall spacers 210. Epitaxial source/drain regions may be subsequently grown from the exposed surfaces 204s, 204t while the fin structures 204 in the p-type device area 226P are covered by the mask layer 228.

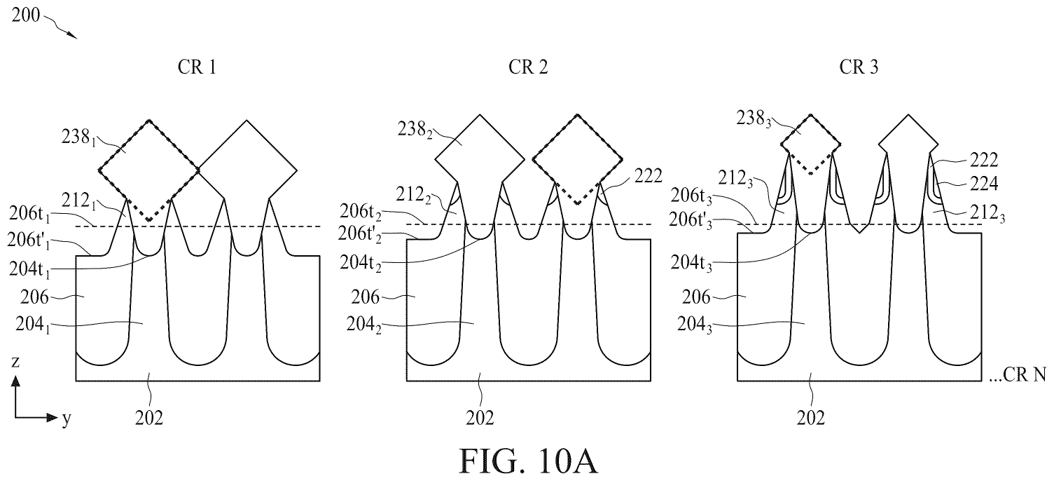

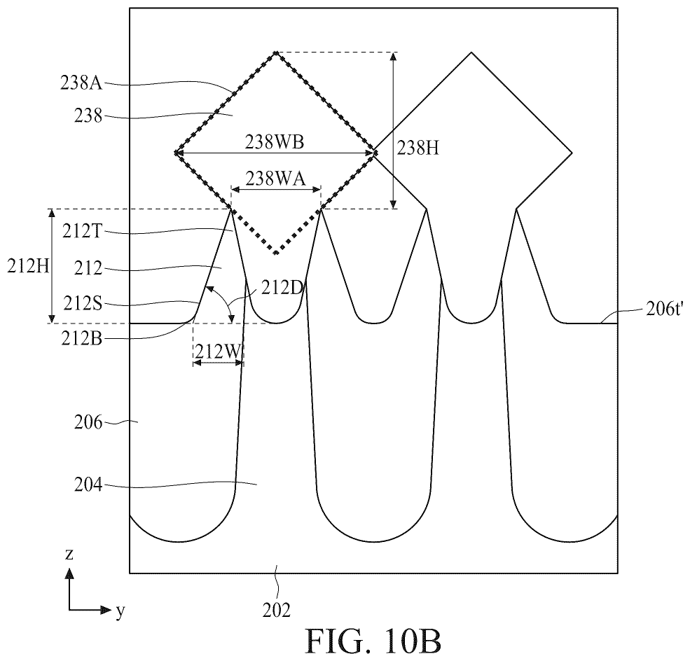

At operation 26, epitaxial source/drain regions 238 are formed from the exposed surfaces 204s, 204t of the fin structures 204 in the n-type device areas 226N in all of the circuit regions CR 1, CR 2, CR 3, as shown in FIG. 10A. The source/drain regions 238₁, 238₂, 238₃ in the circuit regions CR 1, CR 2, CR 3 have identical composition. The epitaxial source/drain regions 238₁, 238₂, 238₃ may be formed by any suitable method, such as by CVD, CVD epitaxy, molecular beam epitaxy (MBE), or any suitable deposition technique. The epitaxial source/drain regions 238 may include one or more layers of Si, SiP, SiC and SiCP. The epitaxial source/drain regions 238 also include n-type dopants, such as phosphorus (P), arsenic (As), etc. In some embodiments, the epitaxial source/drain regions 238 may be a Si layer including phosphorus dopants.

The epitaxial source/drain regions 238₁, 238₂, 238₃ for in the circuit regions CR 1, CR 2, CR 3 are formed simultaneously in the same process. As shown in FIG. 10A, the epitaxial source/drain regions 238₁, 238₂, 238₃ have different physical dimensions suitable for the improved circuit performance in the corresponding circuit regions CR 1, CR 2, CR 3.

FIG. 10B is an enlarged view of the circuit regions CR1, CR2, CR3 showing dimension details of the source/drain regions 238 (238₁, 238₂, 238₃). As shown FIG. 10B, the fin sidewall spacer portions 212 (212₁, 212₂, 212₃) have a top point 212T (212T₁, 212T₂, 212T₃) and a bottom point 212B. The bottom point 212B (212B₁, 212B₂, 212B₃) is in contact with the top level 206t′ (206t′₁, 206t′₂, 206t′₃) of the isolation region 206. A sidewall 212S (212S₁, 212S₂, 212S₃) extends from the top point 212T (212T₁, 212T₂, 212T₃) and the bottom point 212B (212B₁, 212B₂, 212B₃). A distance from the bottom point 212B (212B₁, 212B₂, 212B₃) to the side wall of the fin structures 204 (204₁, 204₂, 204₃) along the y-direction is referred to as a fin sidewall bottom width 212W (212W₁, 212W₂, 212W₃). A distance from the bottom point 212B (212B₁, 212B₂, 212B₃) to the top point 212T (212T₁, 212T₂, 212T₃) along the z-direction is referred to as a fin sidewall height 212H (212H₁, 212H₂, 212H₃). The sidewall 212S (212S₁, 212S₂, 212S₃) and the x-y plane form a fin sidewall angle 212D (212D₁, 212D₂, 212D₃).

As shown in FIG. 10B, the source/drain regions 238 (238₁, 238₂, 238₃) grow from the fin structures 204 (204₁, 204₂, 204₃) restrained by the fin sidewall spacer portions 212 (212₁, 212₂, 212₃) until reaching the top point 212T (212T₁, 212T₂, 212T₃), and then along crystalline facets. A width 238WA (238WA₁, 238WA₂, 238WA₃) of the source/drain regions 238 (238₁, 238₂, 238₃) at the top point 212T (212T₁, 212T₂, 212T₃) correspond to critical dimension of the fin structures 204 (204₁, 204₂, 204₃). A source/drain width 238WB (238WB₁, 238WB₂, 238WB₃) is the width at the widest portion of the source/drain regions 238 (238₁, 238₂, 238₃). The source/drain width 238WB (238WB₁, 238WB₂, 238WB₃) may be referred to as the critical dimension of the source/drain width 238WB (238WB₁, 238WB₂, 238WB₃). A source/drain height 238H (238H₁, 238H₂, 238H₃) is a distance from the top point 212T (212T₁, 212T₂, 212T₃) to the highest point of the source/drain regions 238 (238₁, 238₂, 238₃). Source/drain areas 238A (238A₁, 238A₂, 238A₃) are substantially distributed above the fin sidewall spacer portions 212 (212₁, 212₂, 212₃).

By tuning the etch back process in operation 22, physical dimensions of the source/drain regions 238 (238₁, 238₂, 238₃) may vary significantly among different circuit regions CR 1, CR 2, CR 3. As described above, the second circuit region CR 2 in the semiconductor device 200 includes digital circuits and is desirable to have a balanced source/drain physical dimension. Thus, physical dimensions of the source/drain region 238₂ in the second circuit region CR 2 may be used as a reference region.

In some embodiments, the source/drain CD 238WB (238WB₁, 238WB₂, 238WB₃) in the circuit regions may be in a range between about 0.2 to about 5.0 times the source/drain CD 238WB₂ of the reference region. The source/drain height 238H (238H₁, 238H₂, 238H₃) may be in a range between about 0.33 to about 3.0 times the source/drain height 238H₂ of the reference region. The source/drain areas 238A (238A₁, 238A₂, 238A₃) may be in a range between about 0.06 to about 15.0 times the source/drain area 238A₂ of the reference region.

The fin sidewall spacer portion 212 (212₁, 212₂, 212₃) may be composed by multiple layers. In some embodiments, the number of dielectric layers in the fin sidewall spacer portion 212 (212₁, 212₂, 212₃) may be equal to or more than dielectric layers in reference region.

The fin sidewall height 212H (212H₁, 212H₂, 212H₃) in the circuit regions may be in a range between about 0.5 to 10 times of the fin sidewall height 212H₂ of the reference region. It has been observed, the fin sidewall height 212H (212H₁, 212H₂, 212H₃) and the fin CD 238WA (238WA₁, 238WA₂, 238WA₃) have most significant influence of shapes of the source/drain regions 238 (238₁, 238₂, 238₃).

In some embodiments, the fin sidewall angle 212D (212D₁, 212D₂, 212D₃) may be 1 degree to 80 degree larger than the fin sidewall angle 212D₂ of the reference region. In some embodiments, the fin CD 238WA (238WA₁, 238WA₂, 238WA₃) may be in a range between about 0.50 and 0.99 of the fin CD 238WA₂ of the reference region.

In some embodiments, the fin sidewall bottom width 212W (212W₁, 212W₂, 212W₃) may be in a range between about 0.50 and 3 times of the fin sidewall bottom width 212W₂ of the reference region.

As discussed above, in some embodiments, the fin sidewall spacer portions 212 may include multiple layers. In a multiple layer structure, except the first layer of the spacer layer, e.g. the spacer layer 222, the height of the second layer, such as the spacer layer 224, and subsequent layers, is equal or smaller than the first spacer layer. In some embodiments, the height of the subsequent spacer layers may be in a range from 1 to 0.1 times the height of the first spacer layer. In some embodiments, the total height of a multiple layer fin sidewall spacer portion is higher than the height of a single layer fin sidewall spacer portion or the total height of a multiple layer fin sidewall spacer portion is in a range from 1.1 to 5 times of the single layer fin sidewall spacer portion.

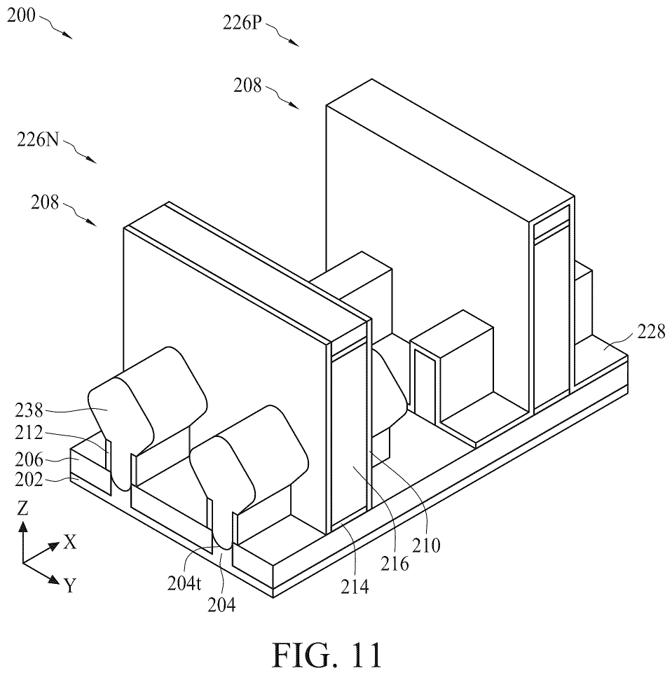

FIG. 11 is a schematic perspective view of a portion of any circuit areas CR 1, CR 2, CR 3 after operation 26. In FIG. 11, a p-type device area 226P and a n-type device area 226N are shown. The source/drain regions 238 in the n-type device area 226N are formed while the fin structures 204 in the p-type device area 226P are covered by the mask layer 228.

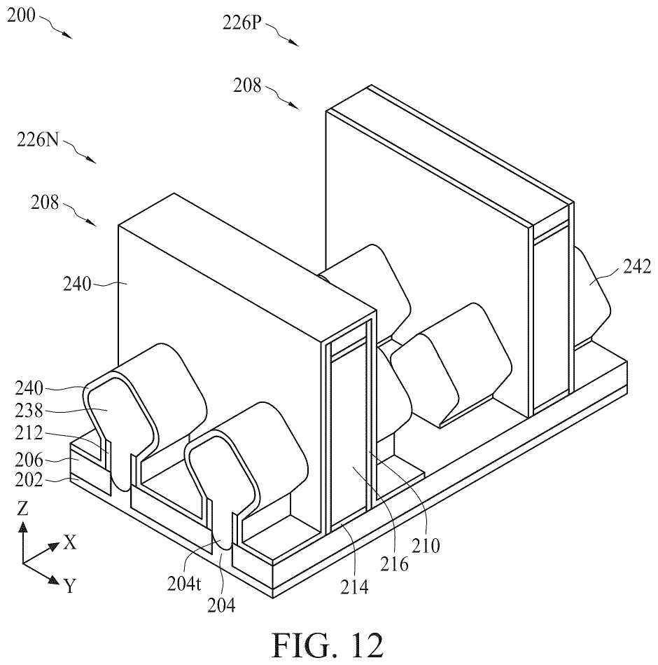

In operation 28, the mask layer 228 is removed so that source/drain regions may be formed on the p-type device area 226P. In operation 20, a second mask layer 240 may be deposited over the semiconductor device 200 and patterned to cover the n-type device area 226N while the p-type device area 226P may be processed, as shown in FIG. 12.

Operations 32, 34, 36 are then performed one or more times to customarily recess etch fin structures 204 in various circuit regions CR 1, CR 2, CR 3. The operations 32, 34, 36 are similar to the operations 20, 22, 24 described above. In operation 38, source/drain regions 242 in the p-type device area 226P are formed in all the circuit regions CR 1, CR 2, CR 3, as shown in FIG. 12.

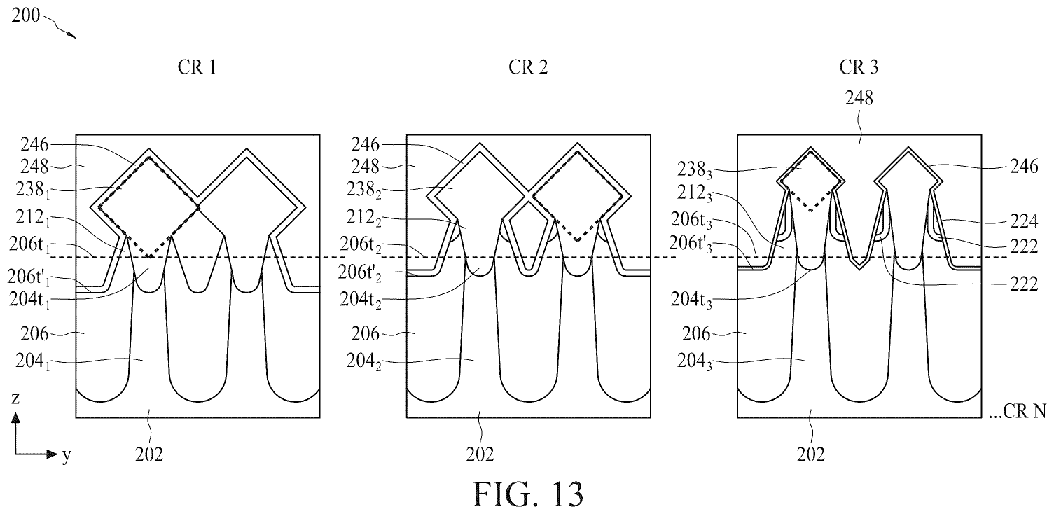

In operation 40, the second mask layer 240 is removed from the n-type device area 226N. In operation 42, a contact etch stop layer (CESL) 246 and an interlayer dielectric (ILD) layer 248 are formed over the semiconductor device 200, as shown in FIG. 13. The CESL 246 is conformally formed over exposed surfaces of the semiconductor device 200. The CESL 246 is formed on the source/drain regions 238, 242, the gate sidewall spacers 210, the fin sidewall spacer portions 212, and the isolation region 206 if exposed. The CESL 246 may include SIN, SiON, SiCN or any other suitable material, and may be formed by CVD, PVD, or ALD.

The interlayer dielectric (ILD) layer 248 is formed over the CESL 246. The materials for the ILD layer 248 include compounds comprising Si, O, C, and/or H, such as silicon oxide, SiCOH and SiOC. Organic materials, such as polymers, may be used for the ILD layer 248. In some embodiments, the ILD layer 248 may be formed by flowable CVD (FCV). The ILD layer 248 protects the epitaxial source/drain regions 238 during the removal of the sacrificial gate structures 208.

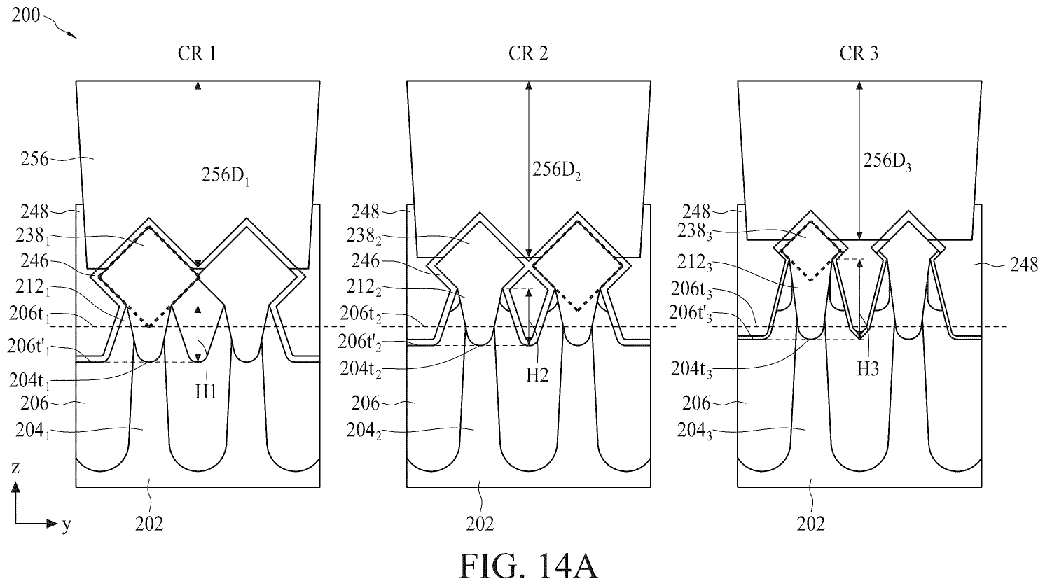

At operation 44, replacement gate structures 250 are formed, as shown in FIGS. 14A-14B. The sacrificial gate dielectric layer 214 and sacrificial gate electrode layer 216 are removed by one or more suitable process, such as dry etch, wet etch, or a combination thereof, to expose the fin structures 204. In some embodiments, a wet etchant such as a tetramethylammonium hydroxide (TMAH) solution is used. The replacement gate structure may include a gate dielectric layer 252, and a gate electrode layer 254.

The gate dielectric layer 252 may be conformally deposited on exposed surfaces in the gate cavities. The gate dielectric layer 252 may have different composition and dimensions for N-type devices and P-type devices and are formed separately using patterned mask layers and different deposition recipes. The gate dielectric layer 93 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂-Al₂O₃) alloy, other suitable high-k dielectric materials, and/or combinations thereof. The gate dielectric layer 252 may be formed by CVD, ALD or any suitable method.

The gate electrode layer 254 is then formed on the gate dielectric layer 252 to fill the gate cavities. The gate electrode layer 254 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSlN, metal alloys, other suitable materials, and/or combinations thereof. In some embodiments, the gate electrode layer 254 may be formed by CVD, ALD, electro-plating, or other suitable method. After the formation of the gate electrode layer 254, a planarization process, such as a CMP process, is performed to remove excess deposition of the gate electrode material and expose the top surface of the ILD layer 248.

At operation 46, source/drain contact features 256 are formed, as shown in FIGS. 14A-14B. Contact holes for the source/drain contact features 256 may be formed by one or more patterning and etch processes to remove the ILD layer 248, the CESL layer 246 to expose a contact surface on the epitaxial source/drain regions 238. A silicide layer may be selectively formed over an exposed surface of the epitaxial source/drain regions 238. In some embodiments, the silicide layer includes one or more of WSi, CoSi, NiSi, TiSi, MoSi, and TaSi. The source/drain contact features 256 are then formed by filling a conductive material in the source/drain contact holes and gate contact holes. In some embodiments, the conductive material layer for the gate contact may be formed by CVD, PVD, plating, ALD, or other suitable technique. In some embodiments, the conductive material for the source/drain contact features 256 includes TiN, TaN, Ta, Ti, Hf, Zr, Ni, W, Co, Cu, Ag, Al, Zn, Ca, Au, Mg, Mo, Cr, or the like. The source/drain contact features 256 may have different depths in the circuit regions. As shown in FIG. 14A, the source/drain contact features 256 have depths 256_{D1}, 256_{D2}, 256_{D3} in circuit regions CR 1, CR 2, CR 3 respectively. In some embodiments, the depths 256_{D1}, 256_{D2}, 256_{D3} (collectively 256D) of the source/drain contact features 256 may be related to the source/drain height 238H (238H₁, 238H₂, 238H₃), shown in FIG. 10A. The source/drain height 238H₁ in the circuit region CR 1 is lower than source/drain height 238H₂ in the circuit region CR 2, and the source/drain height 238H₂ in the circuit region CR 2 is lower than source/drain height 238H₃ in the circuit region CR 3, resulting in the depth 256_{D1} greater than the depth 256_{D2}, which is greater than the depth 256_{D3}.

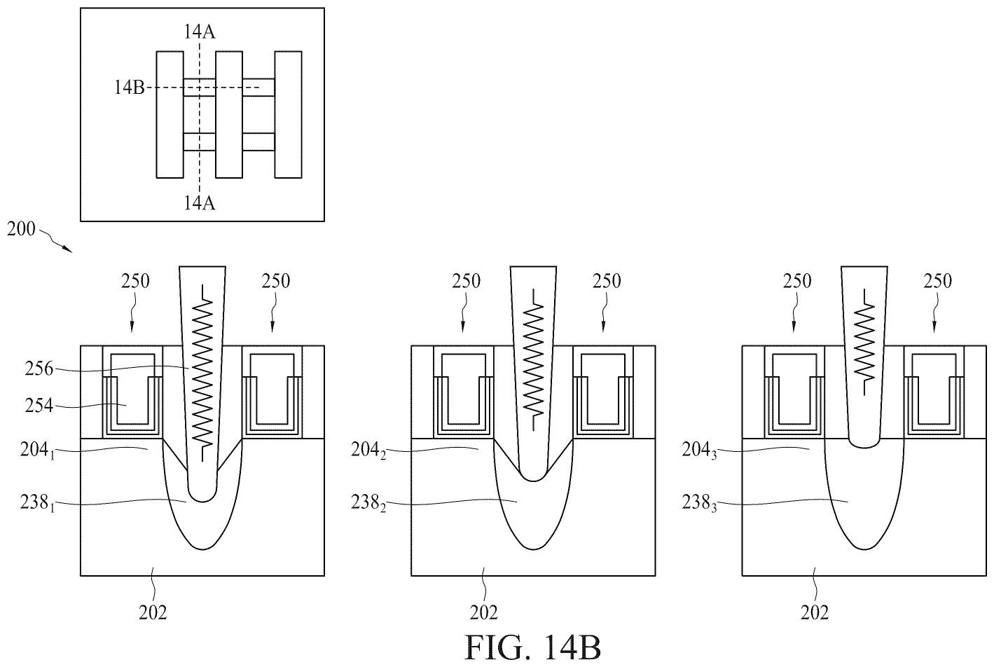

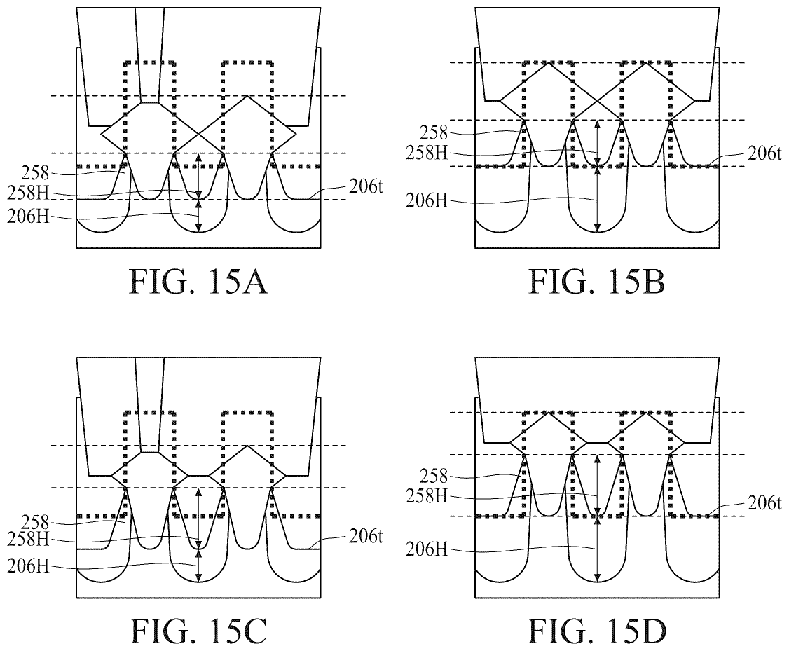

FIG. 15A-15D schematically illustrates modulation of source/drain regions to according to circuit design. As discussed above, Cgd and Rc may be tuned individually for different circuit regions. By modulating height 258H of the fin sidewall dielectric 258 and height 206H of the isolation region 206, embodiments of the present disclosure may tune Cgd and Rc individually. The fin sidewall dielectric 258 include dielectric materials disposed on sidewalls of the fin structures 204 and protruding from the top surface 206t of the isolation region 206 in the trench between neighboring fin structures 204. Depending on the process, the fin sidewall dielectric 258 may include materials of the isolation region 206, and optionally, one or more layers of the sidewall spacers. The height 206H of the isolation region 206 is defined between the top surface 206t of the isolation region 206 and the bottom of the fin structures 204. Cgd correlates to the size of the source/drain regions 238, which may be controlled by the height 258H of the fin sidewall dielectric 258. Rc correlates to both size of the source/drain regions 238 and the height 206H of the isolation region 206.

In FIG. 15A, the height 206H of the isolation region 206 is low and the height 258H of the fin sidewall dielectric 258 is low, resulting in a high Cdg and a high Rc. In FIG. 15B, the height 206H of the isolation region 206 is high and the height 258H of the fin sidewall dielectric 258 is low, resulting in a high Cdg and a low Rc. In FIG. 15C, the height 206H of the isolation region 206 is low and the height 258H of the fin sidewall dielectric 258 is high, resulting in a low Cdg and a high Rc. In FIG. 15D, the height 206H of the isolation region 206 is high and the height 258H of the fin sidewall dielectric 258 is high, resulting in a low Cdg and a low Rc.

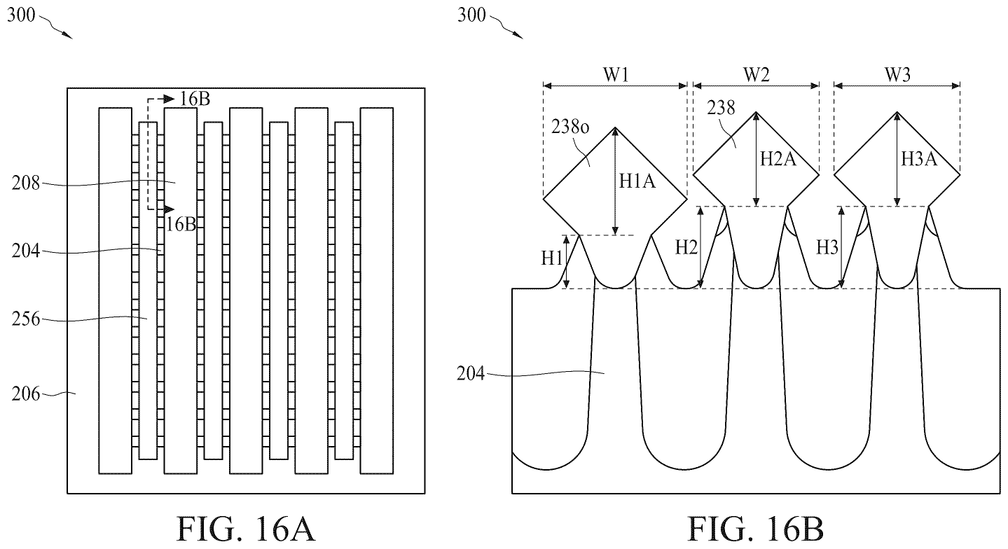

FIGS. 16A-16B schematically illustrate a semiconductor device 300 according to embodiments of the present disclosure. FIG. 16A is a plan view of the semiconductor device 300. The semiconductor device 300 includes multiple fin structures 204. In some embodiments, the number of fin structures 204 may be greater than three. When the fin structures 204 are densely arranged, dimensions of the source/drain regions 238 on each fin structure 204 of the same device may be different due to process loading effects, such as loading effects in lithography, etching, epitaxial growth, and the like. FIG. 16B is a cross section of the semiconductor device 300 showing several fin structures 204 near the edge. As shown in FIG. 16B, the source/drain region 2380 on the outer most fin structure 204 is smaller than the source/drain regions 238 on other fin structures 204. When comparing source/drain regions 238 in different circuit regions, dimensions of the source/drain regions 238 on the outer most fin structures 204 are excluded.

Even though FinFET devices are discussed, embodiments of the present disclosure can be applied to GAA devices.

Various embodiments or examples described herein offer multiple advantages over the state-of-art technology. By modulating recess etch processes in different circuit regions, source/drain regions of different physical dimensions may be formed on the same chip during the same epitaxial deposition process, therefore achieving improved performances for different circuit regions.

Some embodiments of the present provide a semiconductor device, comprising: a first fin structure formed on a substrate; a first source/drain region formed on the first fin structure, wherein the first source/drain region has a first area; a second fin structure formed on the substrate; and a second source/drain region formed on the second fin structure, wherein the second source/drain region has a second area, and a ratio of the first area over the second area is in a range between about 1 and about 15.

Some embodiments of the present disclosure provide a semiconductor device, comprising: a first circuit region formed on a substrate, wherein the first circuit region comprises first source/drain regions, and the first source/drain regions have a first width; a second circuit region formed on the substrate, wherein the second circuit region comprises second source/drain regions, and the second source/drain regions have a second width; wherein the first source/drain regions and the second source/drain regions have identical composition, and the first width is greater than the second width.

Some embodiments of the present disclosure provide a method for forming a semiconductor device, comprising: forming a first fin structure in a first circuit region and a second fin structure in a second circuit region on a substrate; forming an isolation region on the substrate and around the first fin structure and the second fin structure; forming a first sacrificial gate structure over the first fin structure and a second sacrificial gate structure over the second fin structure; depositing a fin sidewall spacer on the first fin structure and the second fin structure; etching back the first fin structure while a first mask layer covers the second circuit region; etching back the second fin structure while a second mask layer covers the first circuit region; and performing an epitaxial deposition to grow a first source/drain region from the first fin structure and a second source/drain region from the second fin structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first fin structure formed on a substrate;
a first source/drain region formed on the first fin structure, wherein the first source/drain region has a first area;
a second fin structure formed on the substrate; and
a second source/drain region formed on the second fin structure, wherein the second source/drain region has a second area, and a ratio of the first area over the second area is in a range between about 1 and about 15.

2. The semiconductor device of claim 1, further comprising:
a third fin structure formed on the substrate;
a third source/drain region formed on the third fin structure, wherein the third source/drain region has a third area, wherein a ratio of the third area over the second area is in a range between about 0.06 and about 1.

3. The semiconductor device of claim 1, further comprising:
an isolation region disposed on the substrate and around lower portions of the first fin structure and the second fin structure;
a first fin sidewall spacer portion disposed on the isolation region and in contact with the first source/drain region; and
a second fin sidewall spacer portion disposed on the isolation region and in contact with the second source/drain region, wherein the first fin sidewall spacer portion is shorter than the second fin sidewall spacer portion.

4. The semiconductor device of claim 3, wherein the isolation region has a first isolation height around the first fin structure and a second isolation height around the second fin structure, and the first isolation height is shorter than the second fin sidewall spacer portion.

5. The semiconductor device of claim 3, wherein the first fin sidewall spacer portion comprises a single dielectric layer, and the second fin sidewall spacer portion comprises two dielectric layer.

6. The semiconductor device of claim 5, wherein the first fin sidewall spacer portion comprises a first dielectric layer, the second fin sidewall spacer portion comprises the first dielectric layer and a second dielectric layer.

7. The semiconductor device of claim 6, wherein the first dielectric layer in the second fin sidewall spacer portion has a greater height than the second dielectric layer in the second fin sidewall spacer portion.

8. A semiconductor device, comprising:
a first circuit region formed on a substrate, wherein the first circuit region comprises first source/drain regions, and the first source/drain regions have a first width;
a second circuit region formed on the substrate, wherein the second circuit region comprises second source/drain regions, and the second source/drain regions have a second width;
wherein the first source/drain regions and the second source/drain regions have identical composition, and the first width is greater than the second width.

9. The semiconductor device of claim 8, wherein the first circuit region comprises analog circuits, and the second circuit region comprises digital circuits.

10. The semiconductor device of claim 9, further comprising:
a third circuit region formed on the substrate, wherein the third circuit region comprises third source/drain regions, and the third source/drain regions have a third width;
wherein the third source/drain regions have the identical composition as the first source/drain regions and the second source/drain regions, and the third width is less than the second width.

11. The semiconductor device of claim 10, wherein the third circuit region comprises radio frequency circuits.

12. The semiconductor device of claim 10, wherein a ratio of the first width over the second width is in a range between about 1.0 and 5.0.

13. The semiconductor device of claim 12, wherein a ratio of the third width over the second width is in a range between about 0.2 and 1.0.

14. A method for forming a semiconductor device, comprising:
forming a first fin structure in a first circuit region and a second fin structure in a second circuit region on a substrate;
forming an isolation region on the substrate and around the first fin structure and the second fin structure;
forming a first sacrificial gate structure over the first fin structure and a second sacrificial gate structure over the second fin structure;
depositing a fin sidewall spacer on the first fin structure and the second fin structure;
etching back the first fin structure while a first mask layer covers the second circuit region;
etching back the second fin structure while a second mask layer covers the first circuit region; and
performing an epitaxial deposition to grow a first source/drain region from the first fin structure and a second source/drain region from the second fin structure.

15. The method of claim 14, wherein
etching back the first fin structure comprises tuning an etching process to etch the fin sidewall spacer on the first fin structure to a first fig sidewall spacer portion having a first spacer height,
etching back the second fin structure comprises tuning an etching process to etch the fin sidewall spacer on the second fin structure to a second fin sidewall spacer portion having a second spacer height,
wherein the first spacer height is lower than the second spacer height.

16. The method of claim 15, wherein the first fin sidewall spacer portion has a first width, the second fin sidewall spacer portion has a second width, and the first width is less than the second width.

17. The method of claim 16, wherein depositing the first fin sidewall spacer comprises:
depositing a first spacer layer on the first and second fin structures;
depositing a second spacer layer on the first spacer layer, wherein the first fin sidewall spacer portion comprises the first spacer layer, and the second fin sidewall spacer portion comprises the first spacer layer and the second spacer layer.

18. The method of claim 14, wherein etching back the first fin structure comprises etching back the isolation region in the first circuit region to a first isolation height,
etching back the second fin structure comprises etching back the isolation region in the second circuit region to a second isolation height,
wherein the first isolation height is lower than the second isolation height.

19. The method of claim 14, wherein the first mask layer is a photoresist layer, and etching back the first fin structure comprises:
depositing the photoresist layer over the substrate;
patterning the photoresist layer to expose the first circuit region;
etching back the first fin structure; and
removing the photoresist layer.

20. The method of claim 15, further comprising forming a hard mask to cover device areas for a first type of devices in the first and second circuit regions, and the first and second source/drain regions are for a second type of devices.
